(19) United States
(12) Patent Application Publication
(10) Pub. No.: US 2026/0321274 A1
(43) Pub. Date: Oct. 15, 2026

(54) AUDIO SOURCE SEPARATION AND AUDIO MIX PROCESSING

(71) Applicant: DOLBY INTERNATIONAL AB, Dublin (IE)

(72) Inventors: Jordi PONS PUIG, Olot (ES); Joan SERRA, Barcelona (ES); Santiago PASCUAL, Barcelona (ES); Giulio CENGARLE, Barcelona (ES)

(73) Assignee: DOLBY INTERNATIONAL AB, Dublin (IE)

(21) Appl. No.: 19/478,947

(22) PCT Filed: Apr. 26, 2024
(86) PCT No.: PCT/EP2024/061581

§ 371 Date: Oct. 27, 2025

Related U.S. Application Data
(60) Provisional application No. 63/512,218, filed on Jul. 6, 2023.

(30) Foreign Application Priority Data
Apr. 28, 2023 (ES) P202330336
Jul. 6, 2023 (EP) 23183758.4

(51) Int. Cl. G10L 21/0272

(52) U.S. Cl. CPC G10L 21/0272

(57) ABSTRACT

A method and system for processing an input audio mix, by extracting at least two source audio signals, each audio source signal representing a separate audio source, extracting audio mix information from the input audio mix, the audio mix information including at least one of audio mix semantic properties and audio mix signal properties, determining audio processing parameters based on the audio mix information, and processing the source audio signals based on the audio processing parameters to generate a processed audio mix. The processing of the sources can thus be based on properties of the input audio mix before source separation, thereby allowing a more automated source processing.

### CROSS-REFERENCE TO RELATED APPLICATIONS

This application claims the benefit of priority from Spanish Patent Application Ser. No. P202330336, filed on 28 Apr. 2023, U.S. Provisional Application No. 63/512,218, filed on 6 Jul. 2023, and European Application No. 23183758.4, filed on 6 Jul. 2023, each of which is incorporated by reference herein in its entirety.

### TECHNICAL FIELD OF THE INVENTION

The present invention relates to separation of an audio mix into audio signals representing separate audio sources, and audio processing based on such source separation. The source separation may be universal, i.e. without requiring prior knowledge about the sources in the audio mix.

### BACKGROUND OF THE INVENTION

Internet and social networks have made the sharing and consumption of user-generated media content (audio and video) a very popular form of entertainment and education. As a consequence, user-generated audio content is abundant and widespread. However, such user-generated audio content is often of inferior quality compared to professional commercial content, and tools that may improve audio quality are desirable.

Separation of different audio sources in an audio mix has been recognized as a key element in audio quality improvement processing. In the past, source separation has been applied as a way to recreate an intended audio mix, using previously obtained knowledge about that mix. Such an approach is disclosed in U.S. Pat. No. 10,944,999 (assigned to the present applicant).

However, there is a need for more generic audio processing tools, which are capable of improving the quality of any audio, also without prior knowledge.

### GENERAL DISCLOSURE OF THE INVENTION

It is an object of the present invention to provide efficient audio processing capable of improving the perceived audio quality of an audio mix.

According to a first aspect of the invention, this and other objects are achieved by a method for processing an input audio mix, the method comprising extracting at least two source audio signals from the input audio mix, each audio source signal representing a separate audio source, extracting audio mix information from the input audio mix, the audio mix information including at least one of audio mix semantic properties and audio mix signal properties, determining audio processing parameters based on the audio mix information, and processing the source audio signals based on the audio processing parameters to generate a processed audio mix.

The method may be embodied as a computer program to be executed by a computer processor.

According to a second aspect of the invention, this and other objects are achieved by a system for processing an input audio mix, the system comprising a source separation module configured to extract at least two source audio signals from the input audio mix, each audio source signal representing a separate audio source, an analytics module configured to receive the input audio mix and to extract audio mix information including at least one of audio mix semantic properties and audio mix signal properties, and to determine audio processing parameters based on the audio mix information, and an editing module configured to receive the extracted audio signals and the audio processing parameters, and to process the source audio signals based on the audio processing parameters to generate a processed audio mix.

According to these aspects, the input audio mix is analyzed, and audio mix information is extracted. This information is used to generate processing parameters, which guide the processing in the editing module. The processing of the sources can thus be based on properties of the input audio mix before source separation, thereby allowing a more automated source processing.

The audio mix semantic properties may include at least one of music genre, type of recording, production style, identified sources in the mix, characteristics of identified sources. For example, the type of recording or production style may have an impact on automatically set processing parameters (e.g. target gains).

The audio mix signal properties may include at least one of loudness, dynamic range, average spectral power, spectral power distribution. Such audio mix signal properties may also have an impact on automatically set processing parameters (e.g. target gains).

The analytics module may further be configured to receive the source audio signals, and the determined audio processing parameters can then be based also on source signal properties of the source audio signals. The source signal properties may include at least one of loudness, dynamic range, average spectral power, spectral power distribution.

The combination of pre-separation audio mix information and post-separation signal properties enables a highly generalized and automated determination of processing parameters. For example, the relative loudness of the sources may be determined and compared to target gains based on the audio mix information. The processing parameters may then indicate a set of gains to be applied to the source audio signals to obtain a desired mix.

In some implementations, the analytics module is further configured to determine source separation parameters based on the audio mix information and/or source signal properties, and the source separation module is configured to receive the source separation parameters and to extract the source audio signals based on the source separation parameters.

Information about the input audio mix, i.e. before signal separation, may provide insights on appropriate methods for source separation. For example, the audio mix information may indicate presence of a specific type of source, e.g. speech, which may indicate use of a speech separator in the source separation module.

The audio processing parameters sent to the editing module may represent linear gains, and the editing module may be configured to mix the extracted audio signals by applying the linear gains to the source audio signals. This is a simple and straightforward type of editing, which may benefit from implementations of the present invention. The gains may be time varying.

In some implementations, the editing module is further configured to process each extracted audio signal individually before mixing, by applying at least one of dynamic range compression, equalization, dynamic equalization or creative effects (e.g. panning).

Other relevant audio processing includes audio editing, rebalancing the volume of sounds in a mix, audio zoom (emphasis of the sources in a specific source/direction), or muting selected sounds; these operations can be performed on device or in the cloud. Such audio editing tools, if automated, can facilitate audio editing for non-professional customers; yet, they are powerful in the sense that they perform operations that are not available in typical professional workflows, therefore they can also be used by professionals in a less automatic way.

In some implementations, the editing module includes a user interface configured to receive user input for controlling the audio processing. This allows user interaction with the editing process, ranging from full manual control to a system assisted manual interaction. For example, the user interface may be configured to provide a user with proposed processing alternatives, and to receive user input associated with said alternatives. Specifically, a selected source may be identified, and a slider may allow a user to increase or decrease loudness of this source (or completely mute it).

A further aspect of the invention relates to a method for universal source separation (sometimes referred to as universal sound separation). This aspect may advantageously be combined with the method according to the first aspect, or be implemented in the source separation module of the second aspect. However, this further aspect is also a separate inventive concept, providing separate technical benefits independently of the first and second aspects.

The method according to the further aspect is a method for universal source separation, comprising receiving an input audio mix, transforming the input audio mix into a frequency domain audio mix spectrogram, binarizing the spectrogram by comparing each tile with a pre-defined threshold value to form a selection mask, applying the selection mask to the audio mix spectrogram to form a spectrogram selection, inverse transforming the spectrogram selection to the time domain, to provide an output audio signal associated with one or several sources in the input audio mix.

As the method does not rely on deep learning models, but only applies threshold analysis of a spectrogram, it is not computationally demanding, and may be executed by relatively light-weight equipment, such as a smart-phone.

If such a method is applied in the source separation of the first or second aspects, the output audio signal may be used as a first source, while the remaining audio mix (the residual audio) may be used as a second source.

### BRIEF DESCRIPTION OF THE DRAWINGS

The present invention will be described in more detail with reference to the appended drawings, showing currently preferred embodiments of the invention.

FIG. 1 is a block diagram of a system according to an embodiment of the present invention.

FIG. 2 illustrates remixing separated sources based on a set of gains.

FIG. 3 shows the principle of universal source (sound) separation.

FIG. 4 is a flow chart of a process for universal source (sound) separation according to an embodiment of the invention.

FIG. 5A shows a spectrogram representing an input audio mix.

FIG. 5B shows a spectrogram representing the same audio mix after pre-emphasis filtering.

FIG. 5C shows a spectrogram representing a selection of the spectrogram in FIG. 5B.

FIG. 5D shows a spectrogram representing the residual of the spectrogram in FIG. 5C.

FIGS. 6A and 6B show frequency spectra representing time slices of the spectrogram in FIGS. 5A and 5B respectively.

### DETAILED DESCRIPTION OF CURRENTLY PREFERRED EMBODIMENTS

Systems and methods disclosed in the present application may be implemented as software, firmware, hardware or a combination thereof. In a hardware implementation, the division of tasks does not necessarily correspond to the division into physical units; to the contrary, one physical component may have multiple functionalities, and one task may be carried out by several physical components in cooperation.

The computer hardware may for example be a server computer, a client computer, a personal computer (PC), a tablet PC, a set-top box (STB), a personal digital assistant (PDA), a cellular telephone, a smartphone, a web appliance, a network router, switch or bridge, or any machine capable of executing instructions (sequential or otherwise) that specify actions to be taken by that computer hardware. Further, the present disclosure shall relate to any collection of computer hardware that individually or jointly executes instructions to perform any one or more of the concepts discussed herein.

Certain or all components may be implemented by one or more processors that accept computer-readable (also called machine-readable) code containing a set of instructions that when executed by one or more of the processors carry out at least one of the methods described herein. Any processor capable of executing a set of instructions (sequential or otherwise) that specify actions to be taken are included. Thus, one example is a typical processing system (i.e. a computer hardware) that includes one or more processors. Each processor may include one or more of a CPU, a graphics processing unit, and a programmable DSP unit. The processing system further may include a memory subsystem including a hard drive, SSD, RAM and/or ROM. A bus subsystem may be included for communicating between the components. The software may reside in the memory subsystem and/or within the processor during execution thereof by the computer system.

The one or more processors may operate as a standalone device or may be connected, e.g., networked to other processor(s). Such a network may be built on various different network protocols, and may be the Internet, a Wide Area Network (WAN), a Local Area Network (LAN), or any combination thereof.

The software may be distributed on computer readable media, which may comprise computer storage media (or non-transitory media) and communication media (or transitory media). As is well known to a person skilled in the art, the term computer storage media includes both volatile and non-volatile, removable and non-removable media implemented in any method or technology for storage of information such as computer readable instructions, data structures, program modules or other data. Computer storage media includes, but is not limited to, physical (non-transitory) storage media in various forms, such as EEPROM, flash memory or other memory technology, CD-ROM, digital versatile disks (DVD) or other optical disk storage, magnetic cassettes, magnetic tape, magnetic disk storage or other magnetic storage devices, or any other medium which can be used to store the desired information and which can be accessed by a computer. Further, it is well known to the skilled person that communication media (transitory) typically embodies computer readable instructions, data structures, program modules or other data in a modulated data signal such as a carrier wave or other transport mechanism and includes any information delivery media.

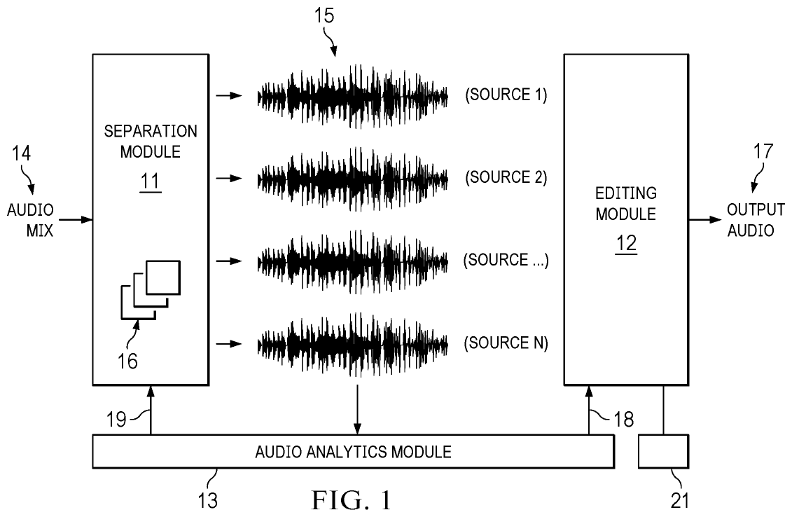

The system 10 in FIG. 1 is composed of three parts; a source separation module 11, an editing module 12, and an audio analytics module 13.

The source separation module 11 is configured to undo any mixing of different source audio signals (“sources”) 15 present in an input audio mix 14. For an artificially created mix, the source separation module serves to estimate the original audio streams (e.g., multi-track recordings) used to create the mix, or at least the most important ones (e.g., vocals, drums, predominant source, etc.). For a direct recording of mixed sources (e.g. a recording of a real event with multiple sound sources), the source separation module serves to estimate the sound contribution from each separate source (e.g. voices, street noise, wind, bird song, etc). Sources obtained by the source separation module can be single (individual) sources (e.g. the speech, dog, car, piano), or composite (group) sources. (e.g. the guitars, children playing) or “stems” (e.g. the backing track or background contextual noise).

The source separation module 11 may employ various source separation models 16 depending on the circumstances. A first type of model may be configured to efficiently remove cross-talk (i.e. “contamination”) from other sources, possibly at the expense of some signal degradation. A second type of model may be configured to preserve excellent signal quality, possibly at the expense of some cross-talk. Both types may be applied in parallel. For example, a model of the first type can be used as a front-end for loudness analysis of the separate sources—a process where the absence of residual components is more important than the signal quality, while a model of the second type can be used to obtain the sources on which further processing and remixing is applied—a task where perceptual quality is of utmost importance).

In some implementations, the source separation module 11 involves a deep learning model that has been pre-trained to extract specific sources from an audio mix. Deep learning models may be very efficient for separation of specific sources, such as speech. However, deep learning models are also useful for “universal” source (sound) separation, i.e. separation of an unknown source given an arbitrary audio mix. Such models can be referred to as “source-agnostic”.

In another implementations the source separation module 11 involves analytical signal processing rather than deep learning. Such an approach may be less computationally demanding, and may therefore run on a portable processing device, such as a smart-phone.

The editing module 12 is configured to process the extracted (separated) sources 15 and re-combine them back to a processed mix 17. For example, in a live recording of a concert, the vocals may sound far away (barely audible). By separating the vocal source in the source separation model 11, editing module 12 can enhance the vocal source to make it louder and more intelligible.

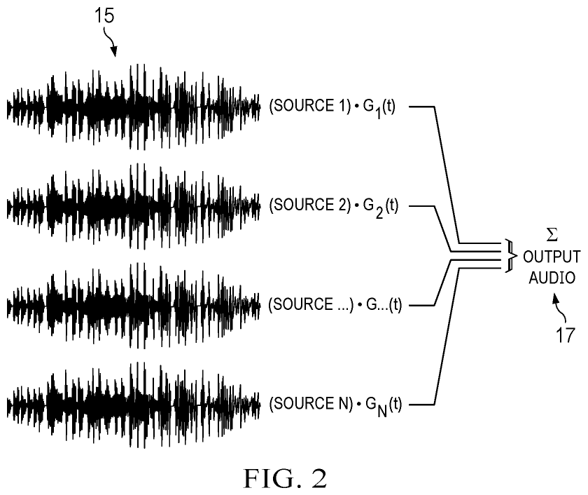

One operation which may be performed on sources 15 is a linear gain G, which corresponds to re-balancing the mix. This is illustrated in FIG. 2. The gain G may be time variable, to ensure a consistent mix in cases where the balance between sources changes across the audio mix (e.g. during a song) in an undesirable way. More advanced processing, such as dynamic range compression, equalization, dynamic equalization or creative effects (e.g., reverb, delay, chorus, flanger, filters, etc.) can be applied. Once the estimated sources are processed, these are remixed to provide the processed audio 17. In some implementations, a final enhancement process can be applied to the processed mix 17, e.g., via using (automatic) audio/music mastering.

The audio analytics module 13 is configured to receive the input audio mix 14 and to extract audio mix information including at least one of audio mix semantic properties and audio mix signal properties. The audio mix semantic properties may include music genre, type of recording, production style, identified sources in the mix, characteristics of identified sources. The audio mix signal properties may include at least one of loudness, dynamic range, average spectral power, spectral power distribution.

The audio analytics module 13 is further configured to determine audio processing parameters 18 based on the audio mix information. The audio processing parameters are provided to the editing module 12 to guide the audio processing. The processing parameters 18 may be determined by a combination of audio analysis, pre-defined rules, artificial intelligence, and user-selected rules.

In the illustrated implementation, the analytics module 13 also receives the separated source audio signals 15, and extracts source signal properties, so that the audio processing parameters 18 are based also on these signal properties.

The audio processing parameters 18 control the editing module 13. For example, with reference to FIG. 2, the mixing gains (G1, G2, . . . GN) can be automatically generated based on the processing parameters 18 from the analytics module 13.

As an example, the gain G of a specific source 15 can be a function of:
Type of source (e.g. speech).
A specified (relative) target level (e.g. 20 dB louder than the background).
Type of recording, as determined by the analysis module (e.g. music, speech or environmental sound).

In one implementation, the analytics module 13 computes the loudness Lᵢ (in dB) of each source 15, a target loudness L_{target,i} is defined for each source, and a gain Gᵢ=L_{target,i}−Lᵢ is computed for each source 15.

Preset target gain levels may be defined based on the scenario. For example, in a speech recording, the background may be set at least 9 dB quieter than the speech, to ensure the speech is intelligible. Preset target gains may also be based on specific instruments with respect to the mix or with respect to other instruments. For example, a target level of +3dB for drums to enhance the drums.

As mentioned, the processing parameters 18 may be time variable. For example, time-varying processing parameters 18 may define gains and processing which are applied only to the time-fragments of the separated sources 15, e.g. only when a specific source 15 is actually present (e.g. a vocal track is amplified only when vocal activity is detected).

In some implementations, the editing module can also apply dynamic range control, equalization or dynamic equalization to further enhance each or some extracted sources individually before remixing them. One approach includes “dynamic EQ” as disclosed in U.S. Pat. No. 11,430,463 for each or some of the sources 15, with a specific target profile chosen according to the type of source (e.g. bass, speech) and the type of recording (e.g. rock music, podcast, environmental).

The profiles for individual separated sources 15 (e.g. bass, speech) and their relative target levels can be obtained by analyzing professional reference content of the same kind using the same analysis and source separation models that are employed in our audio editing pipeline. These target values can be obtained from a specific audio (suitable for making the input content “sound like” the reference audio), or from a statistical analysis of a collection of audio (suitable for making the input content sound “correct” according to common professional criteria).

The processing parameters 18 may also control the editing module 14 to process individual source signals 15 before remixing them. For example, if the audio analytics module 13 identifies one source as dialogue, the audio processing parameters may cause the editing module 13 to apply speech-specific signal processing to this source.

In some applications, requiring manipulation of the sound sources 15 with more artistic freedom, more complex audio effects can be applied (such as reverb, delays, etc.). Other creative effects may include spatial manipulation of content, such as:
Upmixing of all or some of the sources, potentially with different width, so that, e.g., the vocals stay located in a narrow front soundstage, while the other instruments are rendered with a wider soundstage.
Panning of sources, e.g., with Dolby Atmos ® panning, where each source can be located in a different position, rendered with size and/or moved along predefined paths.

Panning may also be done to correct audio imaging problems, e.g. re-panning vocals to the center, while keeping the original position of other instruments. Such re-panning of sources can be done in different ways:
By keeping the extracted sources in their original multichannel format, and changing the balance between channels; for example, from a stereo song the vocals are extracted in stereo, and they can be re-panned by altering the relative gains between L and R.
By downmixing the extracted sources to mono or stereo, and feeding them into a channel-based panner together with specific position parameters, to render them into the target multichannel format; for example, the mono idling car extracted from a mono recording can be panned to the rear Ls, Rs channels of the 5.1 surround.
By downmixing the extracted sources to mono or stereo, adding positional metadata, and turning them into object-based content to be authored as layout-independent content; for example, the stereo piano from the original stereo song can be downmixed to mono and turned into an Atmos object located in the center of the ceiling with a specified size, to be rendered in that position by each playback device to the best of its capabilities.

In some implementations, the analytics module is further configured to determine source separation parameters 19 based on the extracted audio mix information and/or source signal properties. The source separation properties 19 are provided to the source separation module 11 to guide the source separation process.

The source separation parameters 19 may influence the choice of source separation model employed in source separation module 11. For example, if the audio analytics module 13 determines that the input audio mix 14 contains substantially two sources (e.g., vocals and piano), the source separation module 11 can employ a model specifically adapted to separate these two sources. Similarly, if the audio analytics module 13 finds that a speech source is present, the source separation module can employ a speech-specific model.

In other words, the audio analytics module 13 may be configured to guide both the separation module 11 and the editing module 12 based on characteristics extracted from the input audio mix 14 and/or the separated sources 15. The source separation process may even be iterative, where signal properties of the separated sources 15 may serve to further adapt and enhance the employed source separation model.

In some implementations, the editing module 12 includes a user interface 21 configured to expose some or all of the editing controls to the user. Full manual control may be suitable for professionals, while an automatic or semi-automatic workflow may be more appropriate for a non-professional. In a semi-automatic workflow the audio analytics module 13 could perform analysis and make some editing decisions, and convey these decisions as processing parameters 18 to the editing module 12. The editing module 12 edit may then present proposals to a user via the user interface 21, and allow fine-tuning by a user. The following lists some examples of automatically generated proposals and optional fine-tuning:
If the analytics module 13 finds there is a predominant source: propose an edit where the predominant source is louder, and expose a slider to fine-tune the sources volume by the user. The predominant source could be e.g. speech, a loud car, a dog barking, a guitar, etc.
If the analytics module 13 finds there is a predominant source: propose an edit where the predominant source is muted (and expose a slider to fine-tune the sources volume by the user).
If the analytics module 13 finds there is background music: propose an edit attenuating or removing the music to avoid copyright infringements.
Propose an edit where the spatial characteristics of the audio are modified (e.g. enhanced width).
If the analytics module 13 finds there is speech: propose an edit that transforms the speech (e.g. transform the voice in a funny way and re-mix it with the original background).
Propose an edit where the background sound is completely changed. For example, change the captured cafeteria background sound to a more relaxing beach background sound, or add background music to your recording.

In a specific implementation, the analytics module 13 receives the input audio mix 14 and identifies 1) the predominant sources, 2) the spectral energy, and 3) the dynamic range of the audio mix 14. Information about the predominant sources is used to select which sources from the source separation module 11 that are appropriate to process individually (e.g. if no speech is identified, the system will not attempt to rebalance the speech). Information about predominant sources, spectral profile, and loudness is used to set global processing parameters (e.g., determine desired dynamic range and spectral profile of the processed audio 17).

In some implementations, a first optimization is performed on the input mix 14, such as dynamic range compression and equalization, in order to obtain a signal that conforms more closely to professional content, and correct any obvious defects that might impair the subsequent source separation module. Such optimization may be performed on the input audio mix 14 before it is provided to the source separation module 11 and audio analytics module 13. Alternatively, it can be an integrated part of these modules, and in that case potentially apply slightly different optimization for each module 11, 13.

As mentioned, the source separation module 11 may include various source separation models 16 adequate in different situations.

In most western-type popular music some sources (e.g., vocals, bass and drums) appear consistently across songs. As a result, most music source separation models are source specific and separate vocals, bass, drums and ‘other sources’. In speech source separation, the different speakers in a mix are typically not known in advance. Therefore, most speech source separation models are speaker agnostic. On the other hand, such models are specifically configured to separate speech.

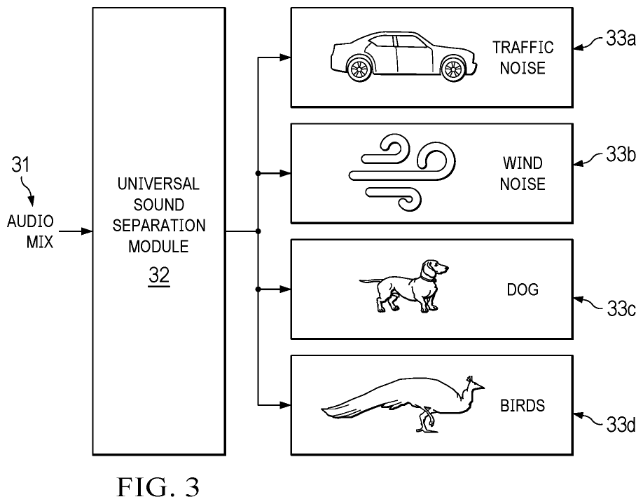

In some applications, a “universal” source (sound) separation model is desired, i.e. a source separation model which is not source specific and can separate any source given an arbitrary audio mix. Such a universal sound separation model can separate mixes such as a user-generated phone recording containing animals and traffic noise. This is illustrated in FIG. 3, where an audio mix 31, here including traffic noise, wind noise, a dog and a bird, is separated by a universal source separation module 32, into four separate source audio signals 33a-d.

Note that universal source (or sound) separation is similar to speech source separation since neither requires prior knowledge of the sources in the mix. However, speech separation models are restricted to a specific domain (speech), while universal sound separation models are truly source agnostic such that they can separate any source given an arbitrary audio mix.

In some implementations, the system 10 in FIG. 1 benefits from such a universal source separation module. In particular, it may be desirable to provide such a universal source separation module which is not computationally heavy, so that it may be executed without significant processing power.

In the following will be described a universal source separation model which may be run on a light-weight processing device such as a smartphone or the like. The universal source separation model does not rely on deep learning models, but on an energy threshold-based approach.

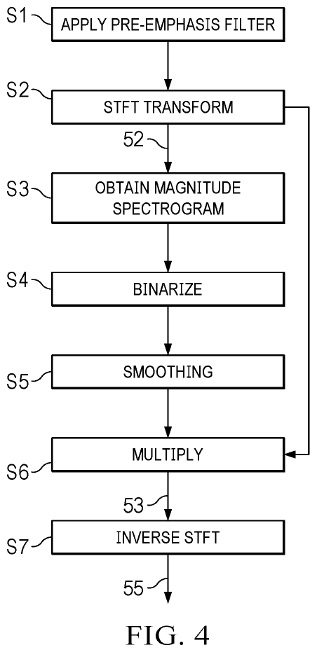

An implementation of the universal sound separation method will now be explained with reference to FIG. 4.

First, in step S1, a pre-emphasis filter is applied to the audio mix 14 in the waveform domain, in order to emphasize higher frequencies. The pre-emphasis filter can be implemented as a time-domain FIR filter P(z)=1−C·z⁻¹, where C is an arbitrary design parameter which can be set to one.

After the pre-emphasis filter is applied the signal is transformed in step S2 into the frequency domain, in this case using the short time Fourier transform (STFT). The STFT transform decomposes the waveform signal into a set of complex sinusoidal bases, and the output is a complex valued spectrogram of the audio mix.

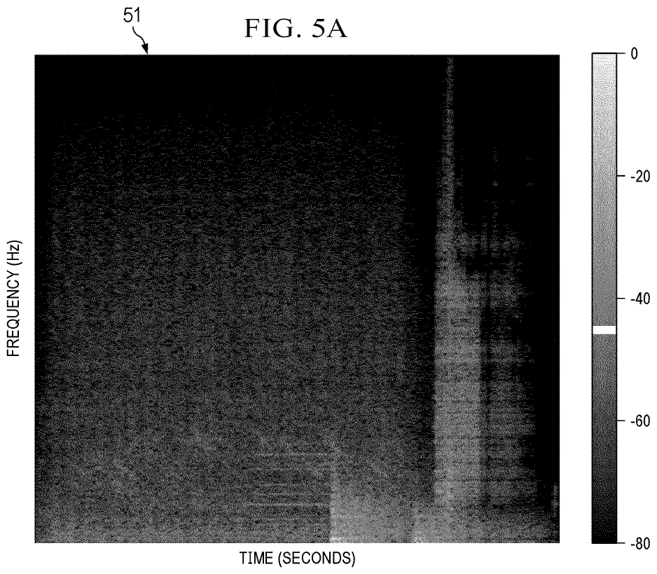

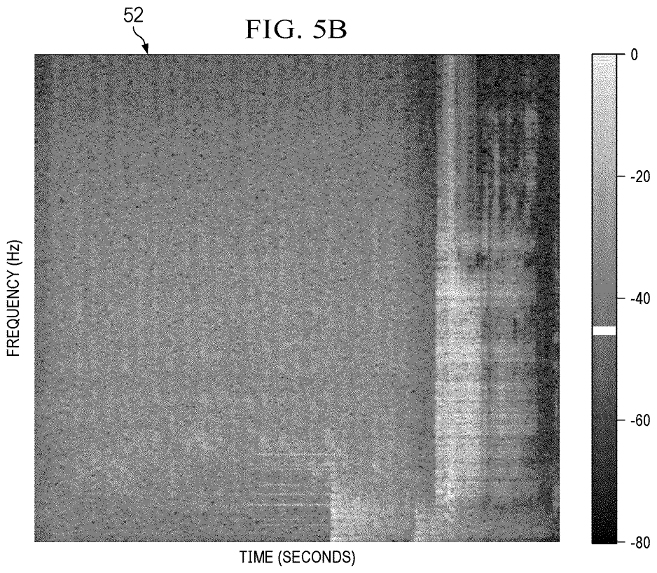

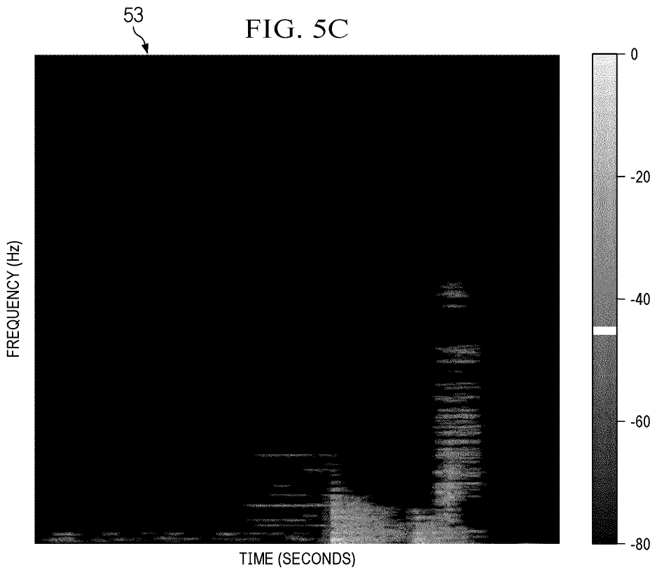

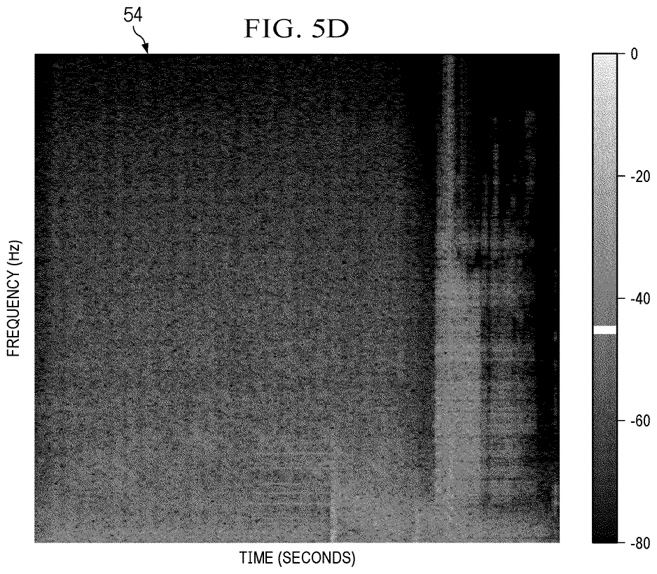

In step S3, a magnitude spectrogram is obtained, representing the magnitudes (or absolute values) of the complex values of the audio mix spectrogram. Put differently, the phase information of the audio mix spectrogram is discarded. FIGS. 5a and 5b show examples of spectrograms 51, 52 as time-frequency plots, where a grey-scale is used to indicate the amplitude of each time-frequency tile. The spectrogram 51 in FIG. 5a represents an input audio mix, while the spectrogram 52 in FIG. 5b represents the same audio mix after pre-emphasis filtering.

Then, in step S4, a binary selection mask is obtained by binarizing the magnitude spectrogram 52 according to a given threshold, i.e. each value is set to one or zero depending on whether the value is above or below the threshold value T. As an example, the threshold T can be set to −45 dB, i.e. values more than 45 dB lower than the maximum value will be set to zero.

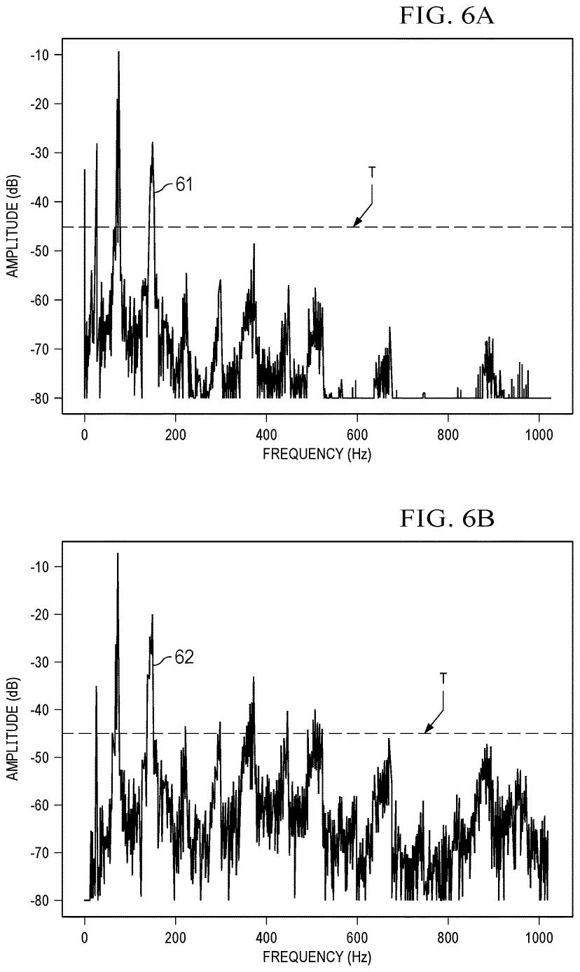

The threshold process is illustrated in FIGS. 6a and 6b, each showing a time-slice 61, 62 of the spectrograms 51 and 52, respectively. As illustrated by FIGS. 6a and 6b, the pre-emphasis filtering serves to include also higher frequencies in the selection.

The selection mask is optionally, in step S5, smoothed along the time, or the frequency dimension, or both. A preferred technique to smoothen the mask is by applying a low-pass filter. The resulting selection mask ranges from 0 to 1 and is of the same size as the audio mix spectrogram.

The selection mask obtained in steps S3-S5 denotes which time-frequency tiles in the spectrogram correspond to a loud source (with mask values close to one) and which do not (mask values close to zero). In step S6, the mask is multiplied with the audio mix spectrogram element-by-element, to provide a spectrogram selection. A spectrogram selection 53 of the filtered audio mix spectrogram 52 is shown in FIG. 5c. FIG. 5d shows the residual spectrogram 54, i.e. the audio mix spectrogram 52 excluding the spectrogram selection 53.

Finally, in step S7, the spectrogram selection 53 is transformed back to the time domain, here by applying an inverse STFT, to form an output signal 55 corresponding to the dominating sound in the input audio mix. In most situations, this dominating sound will in turn be associated with one or several audio sources. In the same way, the residual spectrogram 54 is inverse transformed to a residual audio signal. These two signals—the output signal and the residual signal, may serve as two source audio signals 15 discussed above on relation to the system in FIG. 1.

Unless specifically stated otherwise, as apparent from the following discussions, it is appreciated that throughout the disclosure discussions utilizing terms such as “processing”, “computing”, “calculating”, “determining”, “analyzing” or the like, refer to the action and/or processes of a computer hardware or computing system, or similar electronic computing devices, that manipulate and/or transform data represented as physical, such as electronic, quantities into other data similarly represented as physical quantities.

It should be appreciated that in the above description of exemplary embodiments of the invention, various features of the invention are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the Detailed Description are hereby expressly incorporated into this Detailed Description, with each claim standing on its own as a separate embodiment of this invention. Furthermore, while some embodiments described herein include some, but not other features included in other embodiments, combinations of features of different embodiments are meant to be within the scope of the invention, and form different embodiments, as would be understood by those skilled in the art. For example, in the following claims, any of the claimed embodiments can be used in any combination.

Furthermore, some of the embodiments are described herein as a method or combination of elements of a method that can be implemented by a processor of a computer system or by other means of carrying out the function. Thus, a processor with instructions for carrying out such a method or element of a method forms a means for carrying out the method or element of a method. Note that when the method includes several elements, e.g., several steps, no ordering of such elements is implied, unless specifically stated. Furthermore, an element described herein of an apparatus embodiment is an example of a means for carrying out the function performed by the element for the purpose of carrying out the embodiments of the invention. In the description provided herein, numerous specific details are set forth. However, it is understood that embodiments of the invention may be practiced without these specific details. In other instances, well-known methods, structures and techniques have not been shown in detail in order not to obscure an understanding of this description.

The person skilled in the art realizes that the present invention by no means is limited to the preferred embodiments described above. On the contrary, many modifications and variations are possible within the scope of the appended claims. For example, other types of audio sources than those mentioned above maybe included in the audio mix. Also, many other types of audio processing may be applied to the separated audio sources.

Various aspects of the present invention may be appreciated from the following Enumerated Example Embodiments (EEEs):
EEE1. A method for processing an input audio mix (14), the method comprising:
extracting at least two source audio signals (15) from the input audio mix, each audio source signal representing a separate audio source;
extracting audio mix information from the input audio mix (14), the audio mix information including at least one of audio mix semantic properties and audio mix signal properties,
determining audio processing parameters (18) based on the audio mix information; and
processing the source audio signals (15) based on the audio processing parameters (18) to generate a processed audio mix (17).
EEE2. The method according to EEE1, wherein the audio mix semantic properties include at least one of music genre, type of recording, production style, identified sources in the mix, characteristics of identified sources.
EEE3. The method according to EEE1 or 2, wherein the audio mix signal properties include at least one of loudness, dynamic range, average spectral power, spectral power distribution.
EEE4. The method according to any one of the preceding EEEs, wherein the audio processing parameters (18) are determined also based on source signal properties of the source audio signals (15).
EEE5. The method according to EEE4, wherein the source signal properties include at least one of loudness, dynamic range, average spectral power, spectral power distribution.
EEE6. The method according to any one of the preceding EEEs, further comprising determining source separation parameters (19) based on the audio mix information, and
extracting said at least two source audio signals based on the source separation parameters (19).
EEE7. The method according to EEE6, wherein the source separation parameters are determined also based on source signal properties of the source audio signals (15).
EEE8. The method according to any one of the preceding EEEs, wherein the audio processing parameters (18) represent linear gains, and further comprising to mix the extracted audio signals by applying the linear gains to the source audio signals.
EEE9. The method according to EEE8, wherein the linear gains are time varying.
EEE10. The method according to any one of the preceding EEEs, further comprising processing each source audio signal (15) individually before mixing, by applying at least one of dynamic range compression, equalization, dynamic equalization or creative effects.
EEE11. The method according to any one of the preceding EEEs, further comprising:
providing a user with proposed audio processing alternatives, and
receiving, via a user interface, user input associated with said alternatives.
EEE12. The method according to any one of the preceding EEEs, further comprising applying dynamic range compression and/or equalization to the input audio mix (14) before extracting the source audio signals (15).
EEE13. A system for processing an input audio mix (14), the system comprising:
a source separation module (11) configured to extract at least two source audio signals (15) from the input audio mix, each audio source signal representing a separate audio source;
an analytics module (12) configured to receive the input audio mix and to extract audio mix information including at least one of audio mix semantic properties and audio mix signal properties, and to determine audio processing parameters (18) based on the audio mix information; and
an editing module (13) configured to receive the extracted audio signals and the audio processing parameters (18), and to process the source audio signals (15) based on the audio processing parameters to generate a processed audio mix (17).
EEE14. The system according to EEE13, wherein the analytics module (13) is further configured to receive the source audio signals, and wherein the determined audio processing parameters (18) are based also on source signal properties of the source audio signals.
EEE15. The system according to EEE13 or 14, wherein the analytics module is further configured to determine source separation parameters (19) based on the audio mix information, and wherein the source separation module is configured to receive the source separation parameters and to extract said at least two source audio signals based on the source separation parameters.
EEE16. The system according to EEE15, wherein the analytics module (13) is further configured to determine the source separation parameters (19) based on the source signal properties of the source audio signals (15).
EEE17. The system according to any one of EEEs 13-16, wherein the audio processing parameters (18) represent linear gains, and the editing module is configured to mix the extracted audio signals by applying the linear gains to the source audio signals.
EEE18. The system according to any one of EEEs 13-17, wherein the editing module (12) is further configured to process each source audio signal (15) individually before mixing, by applying at least one of dynamic range compression, equalization, dynamic equalization or creative effects.
EEE19. The system according to any one of EEEs 13-18, wherein the editing module (12) includes a user interface (21) configured to receive user input for controlling the audio processing.
EEE20. The system according to EEE19, wherein the user interface (21) is configured to provide a user with proposed processing alternatives, and to receive user input associated with said alternatives.
EEE21. The system according to any one of EEEs 13-20, wherein the source separation module (11) is configured to apply dynamic range compression and/or equalization to the audio mix before extracting the source audio signals.
EEE22. A computer program product comprising computer program code portions configured to perform the method according to one of EEEs 1-12 when executed on a computer processor.
EEE23. A method for source separation, comprising:
receiving an input audio mix (14);
transforming the input audio mix into frequency domain audio mix spectrogram (51);
binarizing the spectrogram by comparing each tile with a pre-defined threshold value (52), to form a selection mask (53);
applying the selection mask to the audio mix spectrogram (51) to form a spectrogram selection (54):
inverse transforming the spectrogram selection (54) to the time domain, to provide an output audio signal (55) associated with one or several sources in the input audio mix.
EEE24. The method according to EEE23, further comprising:
applying a pre-emphasis filter to the input audio mix (14) before the transforming step, thereby amplifying higher frequencies with respect to lower frequencies.
EEE 25. The method according to EEE 23 or 24, further comprising smoothing the selection mask along the time and/or frequency dimension before applying it to the audio mix spectrum (51).

1. A method for processing an input audio mix, the method comprising:
extracting in a separation module at least two source audio signals from the input audio mix, each audio source signal representing a separate audio source;
extracting in an audio analytics module audio mix information from the input audio mix, the audio mix information including at least one of audio mix semantic properties and audio mix signal properties,
determining in said audio analytics module audio processing parameters based on the audio mix information; and
processing in an editing module the source audio signals based on the audio processing parameters to generate a processed audio mix.

2. The method according to claim 1, wherein the audio mix semantic properties include at least one of music genre, type of recording, production style, identified sources in the mix, characteristics of identified sources.

3. The method according to claim 1, wherein the audio mix signal properties include at least one of loudness, dynamic range, average spectral power, spectral power distribution.

4. The method according to any one of the preceding claims, wherein the audio processing parameters are determined also based on source signal properties of the source audio signals.

5. The method according to claim 4, wherein the source signal properties include at least one of loudness, dynamic range, average spectral power, spectral power distribution.

6. The method according to claim 1, further comprising determining source separation parameters based on the audio mix information, and
extracting said at least two source audio signals based on the source separation parameters.

7. The method according to claim 6, wherein the source separation parameters are determined also based on source signal properties of the source audio signals.

8. The method according to claim 1, wherein the audio processing parameters represent linear gains, and further comprising to mix the extracted audio signals by applying the linear gains to the source audio signals.

9. (canceled)

10. The method according to claim 1, further comprising processing each source audio signal individually before mixing, by applying at least one of dynamic range compression, equalization, dynamic equalization or creative effects.

11. (canceled)

12. The method according to claim 1, further comprising applying dynamic range compression and/or equalization to the input audio mix before extracting the source audio signals.

13. A system for processing an input audio mix, the system comprising:
a source separation module configured to extract at least two source audio signals from the input audio mix, each audio source signal representing a separate audio source;
an analytics module configured to receive the input audio mix and to extract audio mix information including at least one of audio mix semantic properties and audio mix signal properties, and to determine audio processing parameters based on the audio mix information; and
an editing module configured to receive the extracted audio signals and the audio processing parameters and to process the source audio signals based on the audio processing parameters to generate a processed audio mix.

14. The system according to claim 13, wherein the analytics module is further configured to receive the source audio signals, and wherein the determined audio processing parameters are based also on source signal properties of the source audio signals.

15. The system according to claim 13, wherein the analytics module is further configured to determine source separation parameters based on the audio mix information, and wherein the source separation module is configured to receive the source separation parameters and to extract said at least two source audio signals based on the source separation parameters.

16. The system according to claim 15, wherein the analytics module is further configured to determine the source separation parameters based on the source signal properties of the source audio signals.

17. The system according to claim 13, wherein the audio processing parameters represent linear gains, and the editing module is configured to mix the extracted audio signals by applying the linear gains to the source audio signals.

18. The system according to claim 13, wherein the editing module is further configured to process each source audio signal individually before mixing, by applying at least one of dynamic range compression, equalization, dynamic equalization or creative effects.

19. (canceled)

20. (canceled)

21. The system according to claim 13, wherein the source separation module is configured to apply dynamic range compression and/or equalization to the audio mix before extracting the source audio signals.

22. (canceled)

23. A method for universal source separation, comprising:
receiving an input audio mix;
transforming the input audio mix into a frequency domain audio mix spectrogram;
binarizing the spectrogram by comparing each tile with a pre-defined energy threshold value, to form a selection mask;
applying the selection mask to the audio mix spectrogram to form a spectrogram selection:
inverse transforming the spectrogram selection to the time domain, to provide an output audio signal corresponding to the dominating sound in the input audio mix, said dominating sound being associated with one or several sources in the input audio mix.

24. The method according to claim 23, further comprising:
applying a pre-emphasis filter to the input audio mix before the transforming step, thereby amplifying higher frequencies with respect to lower frequencies.

25. The method according to claim 23, further comprising smoothing the selection mask along the time and/or frequency dimension before applying it to the audio mix spectrum.
